(19) United States
(12) Patent Application Publication
(10) Pub. No.: US 2025/0125584 A1
(43) Pub. Date: Apr. 17, 2025

(54) DISTRIBUTED FEEDBACK LASERS WITH TUNABLE DISTRIBUTED BRAGG REFLECTOR INTEGRATION

(71) Applicant: Freedom Photonics LLC, Goleta, CA (US)

(72) Inventor: Gordon Barbour Morrison, Summerland, CA (US)

(21) Appl. No.: 18/913,726

(22) Filed: Oct. 11, 2024

Related U.S. Application Data
(60) Provisional application No. 63/590,330, filed on Oct. 13, 2023.

(51) Int. Cl. H01S 5/12; H01S 5/065

(52) U.S. Cl. CPC H01S 5/12; H01S 5/065

(57) ABSTRACT

A modified distributed feedback (DFB) laser comprises a gain region with a distributed feedback grating and a back reflector that receives a portion of laser light generated by the gain region and the distributed feedback. The back reflector is a wavelength-selective reflector that retroreflects the portion of the received laser light back to the gain region, thereby stimulating single mode laser oscillation and/or improving a side mode suppression ratio (SMSR) of the laser light generated by the modified DFB laser. The spectral properties of the laser output by the modified DFB laser can be independent of position of a cleaved facet of the laser chip near a back end of the modified DFB laser and/or the performance of the modified DFB laser can be maintained over a large number of laser chips separated from a wafer.

### CROSS-REFERENCE OF RELATED APPLICATION

This application claims the benefit of U.S. Provisional Application No. 63/590,330, filed on Oct. 13, 2023, which is incorporated herein in its entirety.

### BACKGROUND

### Field of the Invention

Various embodiments of this application relate to the semiconductor distributed feedback lasers, and in particular semiconductor distributed feedback lasers having high side mode suppression ratios, which can be produced with high yield.

### Description of the Related Art

The spectrum of laser light output by a distributed feedback laser (DFB) is highly sensitive to the distance or alignment between a reflective back facet of the DFB laser and a diffraction grating that provides distributed optical feedback to light produced by an optical gain medium to generate the laser light. For example, the position of the back facet with respect to the diffraction grating (e.g., with respect to a last grating period intercepted by the back facet) can affect the ratio between the amplitudes of two longitudinal modes that are sustained by the diffraction grating as they are amplified by the optical gain medium. A proper longitudinal distance and/or alignment of the back facet with respect to a grating period can result in a large side mode suppression ratio (SMSR) in the output laser light and effective generation of a single mode laser beam having a single peak wavelength associated with a single longitudinal mode sustained by the diffraction grating. In contrast, at an arbitrary longitudinal distance between the back facet and the diffraction grating period, the SMSR can be small and the laser output may comprise a two-mode laser output having at least two distinct peak wavelengths. Due to uncertainties of the manufacturing process, in particular the wafer cleaving process, it may be difficult to maintain a precise alignment (longitudinal alignment) between the reflective back facet and the diffraction grating over a large number of laser chips formed by cleaving a wafer. As a result, the production yield of single mode DFB lasers with large SMSRs can be limited by the manufacturing process and the spectral performance of the DFB laser chips separated from a single wafer can be different and unpredictable due to random distance or alignment between the back facet and the grating for different laser chips produced.

### SUMMARY

In one aspect a distributed feedback (DFB) laser comprises: a pumped gain region comprising an optical gain medium configured to amplify light having wavelength within an operational wavelength range of the DFB; a first diffraction grating providing distributed optical feedback to the light amplified by the pumped gain region, the first diffraction grating extending from a back end to a front end along a longitudinal direction and configured to sustain laser oscillation within the DFB laser to produce laser light; a back reflector configured to retroreflect laser light received from the back end of the first diffraction grating back to the first diffraction grating; and a phase control section disposed along the longitudinal direction between the back reflector and the back end of the first diffraction grating, the phase control section configured to control the spectrum of the laser light. The gain region, the first diffraction grating, and the back reflector are formed on a common substrate.

The first diffraction grating can include a distributed Bragg reflector (DBR) or a sampled grating distributed Bragg reflector (SGDBR). The back mirror can include a cleaved facet, or a wavelength selective reflector such as a DBR or an SGDBR. A reflection band of the wavelength selective reflector can be tunable via electro-optic, thermo-optic effects, or by current injection. The phase control section can be configured to control the spectrum of the laser light by controlling a phase of light transmitted through the phase control section between the first diffraction grating to the back mirror. A portion of the phase control section may be configured to provide optical gain. The phase of light passing through the phase control section and the wavelength of light reflected by the back reflector may be controlled by a phase control signal and a wavelength control signal, respectively. The phase control signal and the wavelength control signal may indicate a measured spectrum, or a measured optical power of the laser light generated and sustained by the DFB laser. The phase control signal and the wavelength control signal may be generated by an optical device that receives the laser light from the DFB laser and is fabricated with the DFB laser on a common substrate. In some cases, one or both of the phase control signal and the wavelength control signal may be generated by measuring a voltage drop across a portion of the optical gain medium.

### BRIEF DESCRIPTION OF THE DRAWINGS

In the following description of the various embodiments, reference is made to the accompanying drawings which form a part hereof, and in which is shown by way of illustration various embodiments of the device. It is to be understood that other embodiments may be utilized, and structural changes may be made.

FIG. 1A is a top view of a distributed feedback (DFB) laser depicting a back facet of the DFB laser and a close-up view of several periods (e.g., variation of refractive index of the laser waveguide) of the corresponding distributed feedback grating, near the back facet.

FIG. 1B shows a calculated output spectrum for three example DFB lasers similar to the DFB laser shown in FIG. 1A, with different longitudinal alignments between an ending period of the distributed feedback grating (DFG) and the corresponding back facets.

FIG. 2A schematically illustrates an example DFB laser with a back reflector in accordance with certain embodiments described herein. The DFB laser comprises a distributed feedback grating (DFG), the back reflector, a phase control section extending between the DFG and the back reflector, and an optical gain region that at least partially overlaps with the DFG.

FIG. 2B schematically illustrates another example DFB laser with a back reflector in accordance with certain embodiments described herein. The DFB laser comprises a DFG, the back reflector, a phase control section extending between the DFG and the back reflector, and an optical gain region that at least partially overlaps with the DFG and the phase control section.

FIG. 2C schematically illustrates another example DFB laser with a back reflector in accordance with certain embodiments described herein. The DFB laser comprises the back reflector and a DFG sharing an interface with the back reflector, and an optical gain region that at least partially overlaps with the DFG.

FIG. 2D schematically illustrates another example DFB laser reflector in accordance with certain embodiments described herein. The DFB laser comprises a DFG and a phase control section extending between the DFG and a back facet, and an optical gain region that at least partially overlaps with the DFG at least in a longitudinal direction.

FIG. 3A schematically illustrates a spectrum of laser light generated by an optical gain medium comprising a sampled grating distributed Bragg reflector (SGDBR) grating (top), and the reflection spectrum of a distributed Bragg reflector (DBR) (bottom). The inset shows the output spectrum of a DFB laser similar to the DFB lasers shown in FIGS. 2A-2C when the DFG comprises the SGDBR, the back reflector comprises the DBR, and a reflection peak of the DBR is aligned with a pair of wavelengths sustained by the SGDBR.

FIG. 3B schematically illustrates a spectrum of laser light generated by an optical gain medium comprising a first SGDBR (top), and the reflection spectrum of a second SGDBR with no optical gain (bottom). The inset shows the output spectrum of a DFB laser similar to the DFB lasers shown in FIGS. 2A-2C when the DFG comprises the optical medium comprising the first SGDBR, the back reflector comprises the second SGDBR, and a reflection peak of the second SGDBR is aligned with a pair of wavelengths sustained by the DFG (first SGDBR).

FIG. 4A schematically illustrates an optical device comprising the DFB laser shown in FIG. 2A or FIG. 2B and a detection section that receives light from a back end of the back reflector.

FIG. 4B schematically illustrates four optical devices similar to the optical device shown in FIG. 4A fabricated on a common substrate and optically coupled to other optical devices fabricated on the common substrate.

FIG. 5A schematically illustrates a cross-section of an example DFB laser similar to the DFB laser shown in FIG. 2B where the gain region comprises a gain layer and the gain layer and the DFG are disposed within a waveguide layer.

FIG. 5B schematically illustrates a side cross-sectional view of an example DFB laser similar to the DFB laser shown in FIG. 2B where the gain region comprises a gain layer and the gain layer and the DFG are disposed above a waveguide layer and within a top cladding layer.

### DETAILED DESCRIPTION

Although certain preferred embodiments and examples are disclosed below, inventive subject matter extends beyond the specifically disclosed embodiments to other alternative embodiments and/or uses and to modifications and equivalents thereof. Thus, the scope of the claims appended hereto is not limited by any of the particular embodiments described below. For example, in any method or process disclosed herein, the acts or operations of the method or process may be performed in any suitable sequence and are not necessarily limited to any particular disclosed sequence. Various operations may be described as multiple discrete operations in turn, in a manner that may be helpful in understanding certain embodiments; however, the order of description should not be construed to imply that these operations are order dependent. Additionally, the structures, systems, and/or devices described herein may be embodied using a variety of techniques including techniques that may not be described herein but are known to a person having ordinary skill in the art. For purposes of comparing various embodiments, certain aspects and advantages of these embodiments are described. Not necessarily all such aspects or advantages are achieved by any particular embodiment. Thus, for example, various embodiments may be carried out in a manner that achieves or optimizes one advantage or group of advantages as taught herein without necessarily achieving other aspects or advantages as may also be taught or suggested herein. It will be understood that when an element or component is referred to herein as being “connected” or “coupled” to another element, it can be directly connected or coupled to the other element or intervening elements may be present therebetween. For clarity of description, “reflector” or “mirror” can be used interchangeably to refer to an optical element (e.g., a grating such as distributed Bragg grating), and/or a surface having a reflectivity greater than or equal to about 1% and less than or equal to 100%. For example, an optical element and/or a surface having a reflectivity greater than or equal to about 1% and less than or equal to 99%, greater than or equal to about 10% and less than or equal to 90%, greater than or equal to about 15% and less than or equal to 80%, greater than or equal to about 20% and less than or equal to 70%, greater than or equal to about 30% and less than or equal to 60%, or any value in any range/sub-range defined by these values can be considered as a reflector or mirror. It will be understood that “light having single wavelength,” “laser light having single wavelength,” “single wavelength light,” “single wavelength laser light,” or “single mode laser light,” can be light comprising wavelengths within a continuous wavelength or frequency band (e.g., a narrowband) centered around a center wavelength (or center frequency). Further, single wavelength mode may comprise a laser generating an output having a side mode suppression ratio (SMSR) greater than 10 dB, greater than 15 dB, or greater than 20 dB between a dominant mode and a side mode. A single mode laser can maintain such SMSRs under different operating temperatures and drive currents.

### Introduction

Distributed feedback (DFB) lasers are a class of lasers that instead of a cavity formed by two or more reflectors (distinct reflectors), use a longitudinally extended diffraction grating (e.g., a Bragg grating) to provide a plurality of optical reflections distributed along an optical gain medium to sustain laser oscillation and generate laser light. The diffraction grating that can be extended along a gain region of the DFB laser is herein referred to as distributed feedback grating (DFG). The output spectrum of a DFB laser can be more stable than a Fabry-Perot (FP) laser and can generate a single-mode beam of light with a relatively clean optical spectrum having a dominant peak significantly larger than other peaks or potentially having a single peak. The stable single-mode operation makes DFB lasers suitable for applications such as optical communication or optical sensing, where the operation of the systems can be highly sensitive to variations of laser wavelengths or presence of multiple wavelengths.

In various implementations, a DFB laser may comprise a DFG (e.g., a Bragg grating) that provides distributed optical feedback along at least a portion of a pumped region of an optical gain medium. When the two ends of the DFB laser (e.g., the two ends of the diffraction grating) are anti-reflection coated, the diffraction grating may support at least two degenerate modes having two different wavelengths (or frequencies), and the DFB laser generates two counter propagating laser beams (e.g., having the same or different wavelengths), and outputs a portion of each laser beam via two opposite ends of the DFG. As a result, such DFB laser generates two output laser beams propagating in different (e.g., opposite) directions and each having at least two peak wavelengths. In some cases, in order to break the modal degeneracy and force the DFB laser to oscillate at a single mode, a back end (e.g., a back facet) of the DFB laser may be coated by a high reflectivity layer to reflect one of the output beams back to the diffraction grating and the pumped gain medium. In some cases, such configuration can result in generation of single-mode (single frequency) laser light exiting the DFB laser via a front end of the DFB laser opposite to the HR coated end.

The output spectrum of a distributed feedback laser (DFB) can be sensitive to the longitudinal alignment/distance between the reflective back facet (the HR coated end) and the diffraction grating. For example, the position of the back facet with respect to a last grating period of the DFG (a period intercepted or terminated by the back facet) can affect the ratio between the amplitudes or optical power of the two degenerate longitudinal modes that are supported by the diffraction grating. A proper alignment between the back facet and the last period (also referred to as the ending period) of the diffraction grating can result in a very large side mode suppression ratio (SMSR) and potentially generation of a single mode output having a single peak wavelength. In contrast, deviation from such proper alignment can result in a small SMSR and generation of a two-mode output having two distinct peak wavelengths. Due to uncertainties of the manufacturing process, in particular the wafer dicing (or cleaving) process, it is difficult to maintain a precise longitudinal distance/alignment between the reflective back facet and the grating period over a large number of laser chips. As a result, the production yield of single mode DFB laser chips, in particular those that generate outputs with large SMSR (e.g., larger than 20 dB), can be limited by the manufacturing process. Additionally, a random longitudinal distance/alignment between the back facet and the grating can result in a poor and unpredictable spectral performance of the DFB laser (e.g., a multimode spectrum with low SMSR).

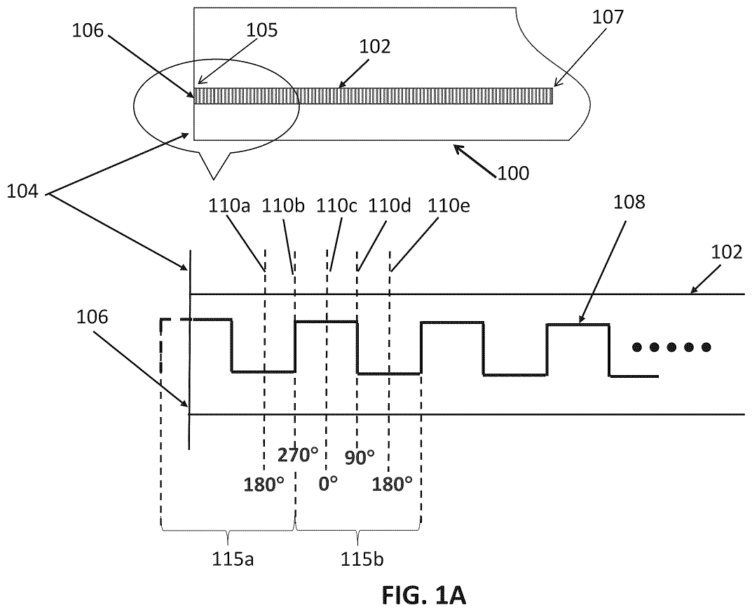

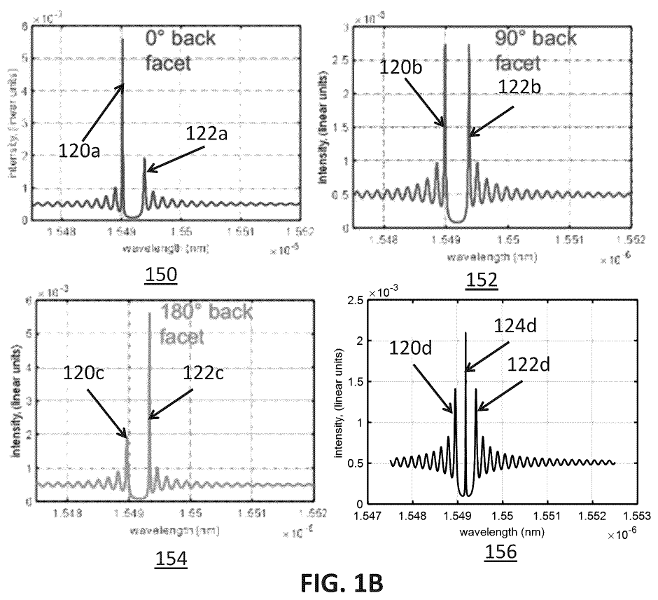

FIG. 1A illustrates a top view of distributed feedback (DFB) laser 102 depicting a back facet 106 of the DFB laser 102 and a close-up view of several periods (e.g., variation of refractive index of the laser waveguide) of the corresponding DFG 108, close to the back facet 106. As discussed above, in some examples, a DFB laser 102 may include a waveguide comprising an optical gain layer or region configured to generate light upon being pumped (e.g., electrically pumped) and the DFG 108 that provides optical feedback to sustain laser oscillation. The DFB laser 102 may be fabricated on a laser die or chip 100, separated from a wafer using a dicing process (e.g., cleaving, cutting, stealth dicing, and the like). The waveguide and the DFG 108 are extended in a longitudinal direction away from an edge of the laser chip 100. In some cases, the edge of the laser chip 100 may be aligned with a back end of the DFB laser 102 to form a back facet of the DFB laser 102. As such, in some cases, a back facet 106 of the DFB laser 102 may comprise a cleaved edge or facet of the laser chip 100. In some cases, the edge 104 of the laser chip 100, and therefore the back facet 106 of the DFB laser 102, may comprise a high reflectivity coating (HR) serving as a back reflector for the DFB laser 102. In some cases, a reflective back facet 106 can modify the spectrum and power of laser light output from the back end 105 or front end 107 of the DFB laser 102. In some cases, the modified spectrum of laser light output from the back end 105 and/or front end 107 may change by changing the longitudinal position of the back facet 106 (e.g., a reflective or highly reflective cleaved facet) with respect to an ending period of the DFG 108. For example, changing the longitudinal position of the back facet 106 (e.g., a reflective or highly reflective cleaved facet) with respect to the ending period 115a (or 115b) of the DFG 108 may change a side mode suppression ratio (SMSR) or a ratio between the optical power of the two longitudinal modes supported by the DFG 108. In some such cases, a proper longitudinal alignment of the back facet 106 (e.g., an HR coated back facet) may reduce or potentially eliminate the contribution of one of the two counter-propagating longitudinal modes of the DFB laser 102 by breaking the optical symmetry of the DFB laser 102. In these cases, the DFB laser 102 may generate a single mode output or an output having a large SMSR.

FIG. 1A also illustrates five example positions 110a-110e of a back facet 106 with respect to the ending periods 115a and 115b of the DFG 108. When the back facet 106 is at position 110a with respect to the ending period 115a, or its equivalent position 110e with respect to the ending period 115b, a facet phase of the back facet (a phase of DFG corresponding to the position of the back facet) is 180 degrees, and when the back facet 106 is at positions 110b, 110c, and 110d, the facet phase is 270 degrees, 0 degrees, and 90 degrees, respectively.

FIG. 1B shows the calculated output spectrum for three example DFB lasers similar to the DFB laser shown in FIG. 1A with different facet phases or different longitudinal alignments between the back facet 106 and a period (e.g., an ending period) of the DFG. The output spectrum 150 corresponds to a case where the back facet 106 is at position 110c (facet phase of 0 degrees). In this case, the amplitude of a dominant mode 120a is larger than a suppressed mode 122a and the corresponding peaks are located at or near the edges of a stopband of the DFG 108. The output spectrum 152 corresponds to a case where the back facet 106 is at position 110d (facet phase of 90 degrees). In this case, the spectrum incudes two dominant peaks (modes) 122b, 120b having substantially equal amplitudes and located at or near the edges of a stopband of the DFG 108. The output spectrum 154 corresponds to a case where the back facet 106 is at position 110e (facet phase of 180 degrees). In this case, the amplitude of a dominant mode 122c is larger than a suppressed mode 120c and the corresponding peaks are located at or near the edges of a stopband of the DFG 108. The output spectrum 156 corresponds to a case where the back facet 106 is at position 110b (facet phase of 270 degrees or equivalently −90 degrees). In this case, the amplitude of the dominant mode 124d located at or near the midpoint of stopband of the DFG 108 is larger than two side modes 120d, 122d located at or near the edges of the stopband. In some cases, changing the facet phase from 0 degrees or 180 degrees to 270 degrees moves the dominant mode from an edge to the center of the stopband. These results indicate that the position of the back facet (or a back reflector) relative to the phase of the DFG determines the output spectrum of the corresponding DFB laser.

In some embodiments disclosed herein, a phase control section having a tunable refractive index may be disposed between the DFG and a back reflector of a DFB laser to control the output spectrum of the DFB laser. In some cases, the back reflector may comprise a back facet, a DBR, or an SGDBR. In some such embodiments, independent of the location of the cleaved facet (location of the cleave point), the effective optical path length between the reflector and the grating can be tuned across a full 360 degrees, thereby allowing access to all effective facet phases and the corresponding output spectrums, some of which are shown in FIG. 1B. The effective phase of such phase control section can be P=360×Y+x+ƒ where Y is a number proportional to the length of the phase control section, ƒ is determined by a cleave position of the facet and x is a tunable phase that can be tuned by controlling the refractive index of the phase control section (e.g., using electro-optical effect, thermo-optical effect, or by current injection). In some embodiments, ƒ may be adjusted (e.g., during the fabrication) to attain a value of P that provides the desired spectrum.

Various designs described herein are capable of improving the production yield of single mode DFB lasers having a high side mode suppression ratio (SMSR) by decoupling the spectral performance of a DFB laser from the alignment between a back facet, or an edge of a chip on which the DFB laser is fabricated, and a DFG that provides distributed optical feedback for light generated and amplified by an optical gain medium. In some cases, the back facet can be a portion of an edge of the chip generated during the manufacturing process (e.g., the dicing or cleaving process). Various designs described herein may reduce or potentially eliminate the impact of the facet phase effects on the performance and production yield of DFB lasers. Some of the DFB laser designs described herein are compatible with existing photonic integrated circuit design architecture where a DFB laser is optically coupled to one or more integrated photonic devices fabricated on a common chip (e.g., via one or more optical waveguides), and/or when the DFB laser does not comprise a cleaved facet.

Example embodiments described herein have several features, no single one of which is indispensable or solely responsible for their desirable attributes. Without limiting the scope of the claims, some of the advantageous features will now be summarized.

In one implementation, a DFB laser comprises an optical gain region (also referred to as gain region) configured to generate and amplify light and a distributed feedback grating (DFG) that at least partially overlaps with the gain region and is configured to provide optical feedback to the light generated and amplified by the gain region. Additionally, the DFB laser includes a back reflector configured to retroreflect light output from a back end of the DFG back to the DFG. The DFB laser may output laser light at least via a front end of the DFG. A location and/or the optical properties of the back reflector may be configured to enhance the SMSR of the laser light. In some cases, the DFG may comprise a sampled grating distributed Bragg reflector (SGDBR) or a Distributed Bragg Reflector (DBR).

Some of the designs described herein may improve the production yield of single mode DFB lasers having a high side mode suppression ratio (SMSR) by including a phase control section between the back reflector (e.g., a cleaved facet) and the DFG of the DFB laser. In some cases, a reflective element may be integrated with the DFB laser and serve as a back reflector for the DFB instead of a cleaved facet. In some cases, integrating one or both the phase control section and the back reflector with the DFB laser can decouple the spectral properties of the laser light generated by the DFB laser (e.g., SMSR and the dominant mode) from the longitudinal alignment between the back facet (e.g., resulting from a dicing or cleaving process), and the DFG of the DFB laser.

The back reflector may be configured to retroreflect light output from a back end of the DFG back to the DFG. In some examples, the back reflector may comprise a wavelength-selective reflector such as a DBR or an SGDBR. In some cases, at least a grating period, a coupling factor of the DBR (or SGDBR) used as a back reflector, can be different from that of the DBR (or SGDBR) used as DFG. In some cases, a reflection band of the back reflector (e.g., a wavelength-selective reflector) can be tunable. In some cases, the reflection band can be tuned to reflect a portion of light received from the DFG (e.g., via a phase control section), back to the DFG to provide a desired output spectrum (e.g., a desired wavelength of a dominant mode). In some examples, the reflection band may be controlled by controlling an electrical current provided to a heating element (e.g., a resistor) disposed on or adjacent to the back reflector. In some examples, the reflection band may be controlled by a current provided to the back reflector.

In some examples, the phase control section (or region) can extend in a longitudinal direction between the DFG and the back reflector and be configured to shift and/or control a phase (an optical phase) of the retroreflected light fed back to the DFG with respect to light received from the DFG. In some cases, an optical path of the phase control section may be controlled by tuning a refractive index (e.g., an effective refractive index) of the phase control section via electro-optical effect, thermo-optical effect, by current injection or any combination thereof. In some examples, the optical length of the phase control section may be controlled by controlling an electrical current provided to a heating element (e.g., a resistor) disposed on or adjacent to the phase control section. In some examples, the optical length of the phase control section may be controlled by controlling a voltage (e.g., a reverse bias voltage) applied on the phase control section. In some examples, the optical length of the phase control section may be controlled by controlling an electrical current (e.g., an injection current) passing through the phase control section. In some examples, the phase control section may comprise a first longitudinal section having a tunable optical path length and a second longitudinal section having a length configured to provide a constant optical phase. In some embodiments, a phase control section may be configured to provide a constant optical phase shift between light entering the phase control section and retroreflected light entering the DFG (e.g., via a back end of the DFG).

In some examples, a phase control electrode may be disposed on or near the phase control section to provide an electrical current or voltage to the phase control section or the heating element adjacent to the phase control section. In some examples, the reflection spectrum of the back reflector 206 can be tunable. For example, a peak reflection wavelength and a reflection band of the back reflector, centered at the peak reflection wavelength, can be adjusted or controlled. In some examples, the DFB lasers 200, 201, or 213 may comprise a wavelength control electrode configured to receive a wavelength control signal from an electric circuit and adjust the reflection spectrum of the back reflector 206 via thermo-optic effect, electro-optic effect, or by carrier injection. In some examples, the wavelength control electrode may be disposed on or near the back reflector to provide an electrical current or voltage to the back reflector or the heating element adjacent to the back reflector.

The phase control electrode can be electrically isolated from the wavelength control electrode and both the phase control electrode and the wavelength control electrode can be electrically isolated from a pump electrode that provides current to the optical gain region.

In some cases, optical properties of one or both of the back reflector and the phase control section can be used to deterministically control and tune the SMSR of the laser output independent of the longitudinal distance between the DFG and an edge or facet of a chip or wafer on which the DFB laser is fabricated. Additionally, in some examples, one or both of the phase control section and the back reflector can be designed, adjusted, or tuned to deterministically adjust or control the optical power of laser light output from a front end and back end of the DFB laser and/or a ratio between the optical power of laser light output from a front end and back end of the DFB laser. In some cases, one or both of the phase control section and the back reflector can be designed or tuned to control or adjust a wavelength of light output by the DFB laser.

### DFB Lasers With Reflector

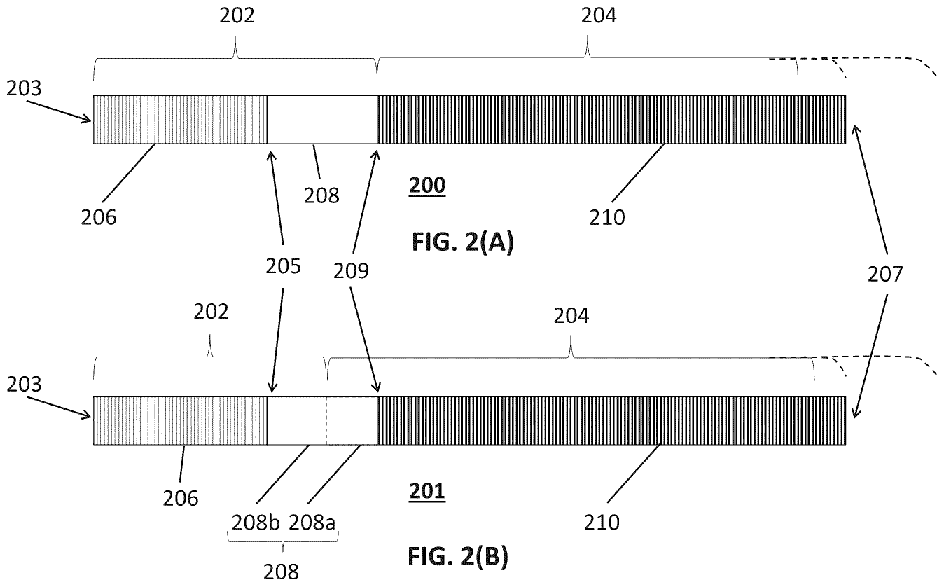

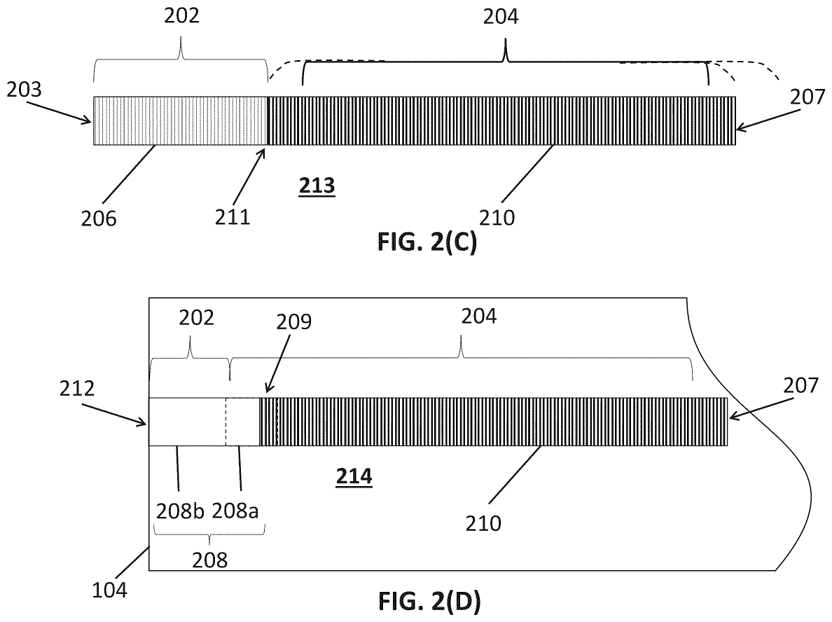

In some cases, a DFB laser may comprise a reflector that receives laser light from the distributed feedback grating (DFG), which sustains laser oscillation, and reflects the received light back to the DFG. FIG. 2A schematically illustrates an example DFB laser 200 with a back reflector 206 in accordance with certain embodiments described herein. It should be understood that reflector 206 is referred to as the back reflector 206 because in this example a front end 207 (or front port) of the DFG 210 is used as the main output port of the DFB laser 200 from which a larger portion of the laser light output by the DFB laser 200 exits the DFB laser. In some examples, the front end 207 may not include a reflective element (e.g., a reflective coating). In some cases, the front end 207 may comprise an anti-reflection coating to reduce optical reflection back to the DFG 210.

The DFB laser 200 comprises a distributed feedback grating (DFG) 210 extending, in a longitudinal direction from a back end 209 (or back port) of the DFG 210 to a front end 207 of the DFG 210, a back reflector 206 (e.g., a DBR) extending, in the longitudinal direction, from a back end 203 of the back reflector 206 to a front end 205 of the back reflector 206, and a phase control section 208 extending, in the longitudinal direction, between the front end 205 of the back reflector 206 to a back end 209 of the DFG 210. In some cases, the DFG 210 may comprise a DFG region (e.g., a DFG region of a waveguide) that supports optical interaction between light at least partially propagating in a gain region and a grating structure (e.g., disposed above or near the DFG region). In various implementations, the DFG 210 may comprise a distributed Bragg grating, a sampled grating distributed Bragg reflector, or other types of gratings configured to provide distributed optical feedback.

In some examples, the DFB laser 200 laser may comprise an optical gain region 204 (also referred to as gain region 204), which amplifies light having a wavelength within an operational wavelength range of the DFB laser 200 (e.g., electrically pumped by an injection electrical current). In some cases, the gain region 204 may comprise a pumped optical gain material. In some examples, the DFB laser 200 can include a pump electrode configured to provide the injection electrical current received from an electrical power supply to the gain region 204. In some cases, the pump electrode may be disposed on the gain region 204. In various implementations, at least a portion of the gain region 204 overlaps with the DFG 210, at least in a longitudinal direction, and amplifies light propagating within the DFG. For example, the DFG 210 may comprise an optical gain material and the gain region may comprise a portion of the DFG 210 that is pumped. In some cases, a length of the gain region 204 may be substantially equal to a length of the DFG 210 (e.g., the entire DFG may provide optical gain), can be smaller than the length of the DFG 210, or can be greater than the length of the DFG 210 (e.g., the gain region 204 may longitudinally extend beyond the front end 207 of the DFG 210).

The DFB laser 200 may further comprise a back region 202 that does not provide optical gain. The gain region 204 and the back region 202 can be non-overlapping regions. In some cases, at least a portion of the back region 202 and the gain region 204 may comprise the same material, but the back region 202 is not pumped. In some other cases, the back region 202 and/or the gain region 204 comprise different materials and/or materials having different bandgaps. In some implementations, the back region 202 comprises the phase control section 208 and the back reflector 206. As such, in some implementations, the phase control section 208 and the back reflector 206 do not provide optical gain while at least a portion of the DFG 210 provides optical gain to laser light having a wavelength within the operational wavelength range of the DFB laser 200.

In the example shown, the gain region 204 may be pumped to generate and amplify light (e.g., within a gain bandwidth of the gain region 204), and the DFG 210 provides optical feedback to amplified light to generate laser light (sustains laser oscillation). A first portion of laser light is output via the front end 207 of the DFG 210, and a second portion of the light exits the DFG 210 via its back end 209, propagates toward the back reflector 206 via the phase control section 208, and becomes incident on the front end 205 of the back reflector 206. Laser light incident on the front end 205 of the back reflector 206 is reflected back (e.g., retroreflected) toward the back end 209 of the DFG 210 through the phase control section 208. In some implementations, the back reflector 206 and the phase control section 208 are configured such that the reflected laser light received by the DFG 210 causes the laser light sustained within the DFG 210, to oscillate at a single longitudinal mode of the DFG 210 and/or have an SMSR larger than a threshold SMSR value or within a specified SMSR range. In some cases, the SMSR can be from 5 dB to 10 dB, from 10 dB to 25 dB, from 25 dB to 30 dB, from 30 dB to 50 dB, or any ranges formed by these values or larger or smaller values.

In some cases, a portion of the light may be output via the front end of the DFG 210 (front end of the DFB 200) and another portion of the single mode laser light may exit from the back end 203 of the back reflector 206 (back end of the DFB 200).

In some examples, the gain region 204 may at least partially overlap with the phase control section 208 at least in a longitudinal direction. As such, at least a portion of the phase control section 208 may provide optical gain to the light transmitted between the DFG 210 and the back reflector 206. FIG. 2B schematically illustrates another example DFB laser 201 with a phase control section 208 comprising a first portion 208a that provides optical gain, and a second portion 208b that does not provide optical gain. The DFB laser 201 may comprise one or more features described above with respect to the DFB laser 200. In some cases, the entire phase control section 208 or at least its first portion 208a, which provides optical gain, and DFG 210 may have substantially the same material composition. In some such cases, the pump electrode, which pumps the gain region 204, may extend over the first portion 208a of the phase control section 208. In some such cases, the pump electrode, which pumps the gain region 204, may comprise two electrically isolated sections for pumping the DFG 210 and the first portion 208a. The second portion 208b can be a passive region or may be used to control the optical path length via the phase control section 208. For example, a phase control electrode, electrically isolated from the pump, may control an optical path length of the second portion 208b of the phase control section 208, e.g., via an electro-optic effect, thermo-optic effect, or by current injection.

In some implementations, the back reflector 206 and the DFG 210 can share an interface such that light is directly transmitted from the DFG 210 to the back reflector 206 and vice versa. FIG. 2C schematically illustrates an example DFB laser 213 having a back reflector 206 sharing an interface 211 with the DFG 210. The DFB laser 213 may comprise one or more features described above with respect to the DFB laser 200. In this case, the gain region 204 at least partially overlaps with the DFG 210 at least in the longitudinal direction, and the back region 202, which does not overlap with the gain region 204, comprises the back reflector 206. In some cases, the gain region 204 extends from the shared interface 211 toward the DFG 210. In some other cases, the gain region 204 extends from a point within the DFG 210 away from the interface 211. In some cases, the gain region 204 can be limited to the DFG 210 or extend in a longitudinal direction beyond the front end 207 of the DFG 210.

In various examples, the back reflector 206 of the DFB lasers 200, 201, and 213 may not provide optical gain. In some examples, the back reflector 206 may comprise a material different from that of the phase control section 208 and/or the gain region 204. In some examples, the back reflector 206 may comprise an optical gain material substantially similar or identical to that of the gain region 204, however the back reflector 206 may not be configured to receive or may not receive any injection current configured to pump the optical gain material.

FIG. 2D schematically illustrates another example DFB laser 214 in accordance with certain embodiments described herein. The DFB laser 214 comprises a DFG 210 and a phase control section 208 extending between the DFG and a back facet 212 (serving as back reflector) formed by a cleaved edge of a laser chip 104 on which the DFB laser 214 is fabricated. The back facet 212 may be configured to retroreflect light received from the back end 209 of the DFG 210 to improve the SMSR and modify the output spectrum of the DFB laser 214. Similar to the DFB laser 201, in some cases, a first portion 208a of the phase control section 208 of the DFB laser 214 may provide optical gain and a second portion 208b may not provide optical gain. In some such cases, the second portion 208b may be used for tuning the optical path length of the phase control section 208. Accordingly, a pump electrode (e.g., used for pumping the gain region 204) can be extended over the first portion 208a of the phase control section 208 to pump the first portion 208a, and a phase control electrode, e.g., electrically isolated from the pump, may provide a phase control signal to the second portion 208b to tune or adjust its optical path length. In some cases, the phase control section of the DFB laser 214 does not provide optical gain (e.g., the first portion 208a is eliminated).

In some cases, at least a portion of the optical path length of the phase control section 208 may be adjusted such that the DFB lasers 200, 201, or 214 oscillates at a single longitudinal mode and outputs a single mode laser light having a desired SMSR. For example, the effective refractive index of at least a portion of the phase control section 208 (e.g., the second portion 208b) may be controlled, e.g., thermo-optically, electro-optically, by current injection, or any combination thereof to provide an optical path length such that a phase shift of light after a roundtrip in the phase control section 208 (from back end 209 to back facet 212 and back to the back end 209), is substantially equal to a desired or target value ±1 degrees, ±5 degrees, ±5%, ±10 degrees, ±15 degrees or smaller. In some cases, tuning the phase control section 208 can be equivalent to changing a facet phase of the DFB laser 102. For example, the phase control section 208 may be tuned to provide an output spectrum similar to the output spectrums 150, 152, 154, 156, or any output spectrum that may result from changing the facet phase of the facet 106 (the alignment of the facet 106 with respect to a period of the DFG 108) from 0 to 360, or 0 to 360×M+Θ degrees where M is an integer, and @ is from 0 to 360 degrees. In some cases, phase control section 208 and the DFG 210 can be electrically isolated and individually controllable. In some cases, a single electrode may provide voltage or current to both phase control section 208 and DFG 210 (e.g., a single electrode may be used to pump at least a portion of the phase control section 208 and at least a portion of DFG 210). In some cases, phase control section 208 and the back reflector 206 can be electrically isolated and individually controllable. In some cases, a single electrode may provide voltage or current to both phase control section 208 and back reflector 206.

In some cases, the phase control section 208 in DFB lasers 200, 201, or 214 may not overlap with the gain region 204. In these cases, the length of the phase control section 208 can be substantially equal to the length of the second portion 208b.

In some cases, a ratio between the length of the first portion 208a, which provides optical gain, and the entire length of phase control section 208 can be from 0 to 10%, from 10% to 20%, from 20% to 30%, from 30% to 40%, from 40% to 50%, from 50% to 60%, or any ranges formed by any of these values or larger or smaller.

In some cases, the first portion 208a of the phase control section 208 may not be used to control a phase of light passing through the phase control section 208 using an electronic control signal (e.g., via electro-optic or thermo-optic effects or using current injection). However, in some such cases, the first portion 208a may provide optical gain.

In some examples, the phase control section 208 may not provide optical gain. In some such examples, a portion of the phase section may be used to control the optical phase of light passing through the phase control section 208 using a control signal and another portion can be a passive portion that provides a constant optical phase delay to the light passing through the phase section.

In some implementations, the phase control section 208 may provide a constant optical phase delay to the light passing through the phase control section 208 and may not be tuned using a control signal to change the optical phase via thermo-optic or electro-optic effects, or current injection.

In some implementations, the DFB lasers 200, 201, or 214 may comprise two or more phase sections in series. For example, the phase control section 208 may comprise two or more longitudinal regions that are controlled by two or more electrically isolated control electrodes using independent control signals.

In some examples, the phase control electrode, which is electrically isolated from the pump electrode, may be configured to receive a phase control signal from an electric circuit (e.g., a control circuit) and control an optical path length of the phase control section 208 based on the phase control signal. For example, upon receiving the phase control signal, the second electrode may generate an electric field or electric current within the phase control section 208 (or a portion of the phase control section 208, such as the second portion 208b). Alternatively, upon receiving the phase control signal, the phase control electrode may generate an electric current in a heating element that is in thermal communication with the phase control section 208. In various implementations, the phase control electrode may be disposed on or near the phase control section 208.

In some examples, the reflection spectrum of the back reflector 206 can be tunable. For example, a peak reflection wavelength and a reflection band of the back reflector, centered at the peak reflection wavelength, can be adjusted or controlled. In some examples, the DFB lasers 200, 201, or 213 may comprise a wavelength control electrode configured to receive a wavelength control signal from an electric circuit and adjust the reflection spectrum of the back reflector 206 via thermo-optic effect, electro-optic effect, or by carrier injection.

In some implementations, the phase and the wavelength control signals provided to the phase control section 208 and the back reflector 206, respectively, can be generated by the electronic circuit. In some cases, the wavelength and/or phase control signals are adjusted during a manufacturing process and/or calibration process and are kept at operational values during the operation of the corresponding DFB laser. For example, a value of the wavelength and/or phase control signal may be adjusted while monitoring an output spectrum (e.g., the output wavelength) and/or an output power of the DFB laser to determine operational values of the wavelength and/or phase control signals corresponding to a desired output spectrum (e.g., single mode spectrum having a desired SMSR) and/or a desired output power.

In some cases, the electronic circuit (or circuit) may dynamically control the wavelength and/or the phase control signals during operation of the corresponding DFB laser. In various implementations, the electronic circuit may dynamically control the wavelength and/or phase control signals based at least in part on a measured output power (output from a back and/or front of the DFB laser), spectrum of laser light output by the DFB laser, and/or a sensor signal received from a sensor that does not receive and/or measure light from the laser (e.g., a temperature sensor). In some cases, the electronic circuit may dynamically control the wavelength and/or phase control signals based at least in part on a measured voltage drop across (e.g., along a lateral path) the gain region (e.g., gain region 204). For example, a voltage drop measured across the thickness of the gain region may be provided to the electronic circuit. In some cases, the voltage drop indicates optical power of laser light oscillating in the DFB laser and thereby an optical power of laser light output by the DFB laser (e.g., via front end, back end, or back mirror). In some cases, the output power and/or the spectrum of laser light output by the DFB laser may be measured by an optical device that is fabricated on the same chip on which the DFB laser is fabricated and is optically coupled to the DFB laser, e.g., via an optical waveguide, to receive laser light generated by the DFB laser.

In some cases, the electronic circuit may comprise a processor that determines, generates, and/or controls the wavelength and/or phase control signals by executing machine readable instructions stored in a non-transitory memory. In some cases, the electronic circuit may execute machine readable instructions stored in a non-transitory memory to determine, generate, and/or control the wavelength and/or phase control signals based at least in part on a measured spectrum and/or optical power of the laser light generated and sustained by the DFB laser. In some examples, the electronic circuit may receive a spectrum signal or optical power signal from an optical device that is fabricated on a chip on which the DFB laser is fabricated and receives at least a portion of the laser light generated and sustained by the DFB laser. In some cases, the optical device may comprise a photodetector. In some cases, the optical device may comprise an optical filter.

In various implementations, a length of the DFG 210 of the DFB lasers 200, 201, 213, and 214, along the longitudinal direction, can be from 100 to 500 micrometers, from 500 to 1000 micrometers, from 1 mm to 5 mm, or any range formed by any of these values, or larger or smaller values.

In various implementations, a length of the phase control section 208 of the DFB lasers 200, 201, and 214, along the longitudinal direction, can be from 5 to 500 micrometers, from 50 to 200 micrometers, from 200 to 500 micrometers, from 500 micrometers to 1 millimeter or any range formed by any of these values, or larger or smaller values.

In various implementations, a length of the back reflector 206 of the DFB lasers 200, 201, and 213, along the longitudinal direction, can be from 1 to 10 micrometers, from 10 to 100 micrometers, from 100 to 1000 micrometers, or any range formed by any of these values, or larger or smaller values. In some cases, e.g., when the back reflector comprises a facet coating, its length can be less than 1 micron.

In some implementations, the phase control section 208 and/or the back reflector 206 may be configured such that a ratio between optical power of laser light output via the front end of the DFG 210 and the optical power of laser light output via the back end 203 of the back reflector is within a range such as an uncertainty range (e.g., ±1% to ±5%, or ±5% to ±10%) from a desired ratio or within a desired range. In some examples, the desired ratio can be 60/40, 70/30, 90/10, 99/1, or a range formed by any of these ratios or other ratios, possibly ratios larger or smaller.

In some implementations, the back reflector 206 may be configured to reflect laser light received from the DFG 210 such that a phase or an amplitude of the reflected light received by the DFG 210 causes the laser light to have a desired spectrum (e.g., a single mode spectrum with an SMSR within a specified range).

In some implementations, an optical path length of the phase control section 208 may be tuned such that a phase shift of the laser light after transmission from the DFG 210 to the back reflector 206 and back to DFG 210 is within a range such as an uncertainty range (e.g., ±15%, ±10%, ±5%, ±2%, ±1%) from a specified value. The specified value may be determined based on a desired spectrum for the laser light (e.g., a single mode spectrum with an SMSR within a specified range). In some cases, tuning the optical path length can change the spectral locations and amplitudes of one or more peaks in the output spectrum of the DFB lasers 200, 201, 213, and 214. For example, the optical path length of the phase control section 208 may be tuned to move a dominant peak with respect to a stopband of the DFG 210 to place the dominant peak close to the middle of band stop and suppress the side modes.

In various implementations, a coupling coefficient of the DFG 210 can be from 0.1 cm⁻¹ to 1 cm⁻¹, from 1 cm⁻¹ to 10 cm⁻¹, from 10 cm⁻¹ to 50 cm⁻¹, from 50 cm⁻¹ to 100 cm⁻¹ or any range formed by any of these values, or larger or smaller. In various implementations, the length of an individual period of the DFG 210 can be from 100 nm to 250 nm, from 250 nm to 500 nm or any range formed by any of these values, or larger or smaller. In some implementations, the length of an individual period of the DFG 210 may be determined based on an operational wavelength of the corresponding DFB laser and/or the material from which the gain region 204 material is formed (herein referred to as gain material). For example, the period of the grating can be equal to the operational wavelength divided by 2×n_{eff} where n_{eff} is the effective refractive index of the gain material. In some cases, the operational wavelength of the DFB laser can be substantially equal to the first order diffraction of the DFG 210. In some cases, the operation wavelength of the DFB laser may be substantially equal to the second order diffraction of the DFB laser. In these cases, the period of the grating can be equal to the operational wavelength divided by n_{eff}. In some examples, the gain material may comprise an III-V semiconductor material having a refractive index from 3 to 3.4.

In some examples, the operational wavelength range of the DFB lasers 200, 201, 213, and 214 can be from 600 nm to 700 nm, from 700 nm to 800 nm, from 800 nm to 900 nm, from 900 nm to 1000 nm, from 1000 nm to 1110 nm, from 1100 nm to 1200 nm, from 1200 nm to 1300 nm, from 1300 nm to 1400 nm, from 1400 nm to 1500 nm, from 1500 nm to 1600 nm, from 1600 nm to 1800 nm, from 1800 nm to 2300 nm, from 2300 nm to 2500 nm, from 2500 nm to 3500 nm, from 3500 nm to 6000 nm or any ranges formed by any of these values or larger or smaller.

In some cases, at least one characteristic of a DBR or SGDBR used as back reflector 206 (e.g., grating period, coupling coefficient, length, number and/or interspacing between bursts in a SGDBR, and the like or any combination of these) can be different than that of a DBR or SGDBR used as DFG 210.

In some cases, the back reflector 206 may comprise a DBR and configuring the back reflector may comprise tuning, specifying, determining, or adjusting, a period, a length, a coupling coefficient of the DBR or any combination of these. In some cases, a coupling coefficient of the DBR can be from 0.1 cm⁻¹ to 1 cm⁻¹, from 1 cm⁻¹ to 10 cm⁻¹, from 10 cm⁻¹ to 50 cm⁻¹, from 50 cm⁻¹ to 100 cm⁻¹ or any range formed by any of these values, or larger or smaller. In some cases, a number of periods of the DBR can be from 5 to 100, from 100 to 1000, from 1000 to 4000, or any range formed by any of these values, or larger or smaller values. In some cases, a reflection bandwidth of the DBR around the peak reflection wavelength can be from 0.5 nm to 1 nm, from 1 nm to 5 nm, from 5 nm to 50 nm, or any range formed by any of these values, or larger or smaller values.

In various implementations, where the back reflector 206 comprises a DBR, a coupling coefficient of the DBR can be larger than that of the DFG 210 by a factor from 1.001 to 1.1, from 1.1 to 1.5, from 1.5 to 2, 2 to 10, 10 to 100 or any range formed by any of these values, or larger or smaller values.

In various implementations, where the back reflector 206 comprises a DBR, a coupling coefficient of the DBR can be smaller than that of the DFG 210 by a factor from 1.001 to 1.1, from 1.1 to 1.5, from 1.5 to 2, 2 to 10, 10 to 100 or any range formed by any of these values, or larger or smaller values.

In various implementations, where the back reflector 206 comprises a DBR, the length of an individual period of the DBR can be the same as that of the DFG 210, or larger or smaller than that of the DFG 210 by a factor from 1.0001 to 1.001, from 1.001 to 1.01, from 1.01 to 1.1, or any range formed by any of these values, or larger or smaller values.

In various implementations, where the back reflector 206 comprises a DBR, a number of periods of the DBR can be smaller than that of the DFG 210 by a factor from 1 to 5, from 5 to 10, or any range formed by any of these values, or larger or smaller values.

In various implementations, where the back reflector 206 comprises a tunable DBR (e.g., electro-optically, thermo-optically, or by current injection), a tuning range of the peak reflection wavelength of the DBR can be from 0.1 to 1 nm, from 1 to 5 nm, from 5 to 20 nm, or any range formed by any of these values, or larger or smaller values.

In some cases, the back reflector 206 may comprise an SGDBR and configuring the back reflector may comprise tuning, specifying, determining, and/or adjusting, a period and/or a coupling coefficient of individual gratings within the SGDBR, an inter-grating spacing, or a total length of the SGDBR or any combination thereof.

In some cases, a coupling coefficient of individual gratings of the SGDBR can be from 10 cm⁻¹ to 20 cm⁻¹, from 20 cm⁻¹ to 50 cm⁻¹, from 50 cm⁻¹ to 100 cm⁻¹, from 100 cm⁻¹ to 600 cm⁻¹, from 600 cm⁻¹ to 1000 cm⁻¹ or any range formed by any of these values, or larger or smaller. In some cases, the number of individual grating bursts in the SGDBR can be from 2 to 4, from 4 to 10, from 10 to 50 or any range formed by any of these values, or larger or smaller values.

In some cases, the back reflector 206 may comprise a wavelength-selective reflector having a reflection spectrum comprising at least one peak reflection wavelength and a reflection bandwidth centered at the peak reflection wavelength. In some cases, the peak reflection wavelength can be tunable (e.g., by a wavelength control signal). In some cases, the back reflector 206 may comprise a grating different from a DBR and SGDBR. In some such cases, configuring the back reflector may comprise tuning, specifying, determining, or adjusting, a period and/or a coupling coefficient of the grating, or a total length of the grating. In some cases, the back reflector grating may be chirped or apodised. In some cases, the back reflector 206 may comprise a reflector (e.g., a tunable reflector) that does not include a grating. For example, the back reflector may comprise a ring resonator reflector that is tuned via thermo-optical effect, electro-optical effect, or by current injection.

In some cases, the back reflector may comprise a multilayer coating on a back facet and configuring the back reflector may comprise specifying, determining, and/or adjusting, a number of layers in a coating, and/or the reflective index and/or the thickness of different layers.

In some cases, configuring the optical path length of the phase control section 208 may comprise tuning, specifying, determining, and/or adjusting, a length, and/or an effective refractive index of the phase control section 208.

In various implementations, a property of the back reflector 206 (e.g., length, grating period or coupling coefficient), and/or an optical length of the phase control section 208, can be configured such that the DFB laser outputs light having a target or desired SMSR. In various implementations, a desired or a target SMSR can be an SMSR larger than the threshold value (e.g., a lower bound) or within an SMSR range. In some examples, the threshold values can be from 10 dB to 20 dB, from 20 dB to 30 dB, from 30 dB to 40 dB, from 40 dB to 50 dB, from 50 dB to 60 dB or any range formed by any of these values, or larger or smaller values. In some examples, SMSR range can include 10 dB to 15 dB, 15 dB to 20 dB, 20 dB to 25 dB, 25 dB to 30 dB, 30 dB to 35 dB, 35 dB to 45 dB, 45 dB to 60 dB or a range formed by any of these values or ranges having larger or smaller bounds.

In some cases, a spectral position of a dominant laser mode (e.g., the largest peak) with respect to a stopband of the DFG 210 may be linked to SMSR of the laser light. In some cases, the output spectrum of the DFB lasers 201, 202, 213, and 214 may be characterized based on the spectral position of a dominant laser mode with respect to the stopband of the corresponding DFG.

In various implementations, a property of the back reflector 206 (e.g., length, grating period or coupling coefficient), and/or an optical length of the phase control section 208, can be configured such that a phase of light reflected back to the DFG 210 relative to the phase of light output from the back end 209 of the DFG 210 is shifted by M×2π+α radian (e.g., ±15%, ±10%, ±5%, ±2%, ±1% or smaller), where a can be tuned from 0 to 360 degrees and M is an integer (e.g., from 0 to ±10, from ±10 to ±100, from ±100 to ±500, from ±500 to ±1000, from ±1000 to ±1500, or any range formed by any of these values or larger values).

In some cases, a tuning range of the phase control section 208 may correspond to tuning the facet phase of the facet 106 of the DFB laser 102 from 0 to 360 degrees. In other words, the phase control section 208 may be tuned to generate an output spectrum similar to the output spectrum of the DFB laser 102 for any facet phase from 0 to 360 degrees.

In some cases, the phase control section 208 may be tuned to generate an output spectrum corresponding to the output spectrum of the DFB laser 102 when the facet 106 is near or at the position 110b (facet phase of 270 degrees).

In various implementations, a property of the back reflector 206 (e.g., a length, a grating period, an inter-grating spacing, or a coupling coefficient), and/or an optical length of the phase control section 208, can be configured such that a ratio between optical power of the laser light output from the front end of the DFB laser (front end of the DFG) and from the back end of the DFB (back end of the back reflector 206) is from 2 dB to 5 dB, from 5 dB to 10 dB, from 10 dB to 15 dB, from 15 dB to 20 dB, from 20 dB to 30 dB, or any range formed by these values, or larger or smaller values.

In various implementations, the back reflector 206, and/or the phase control section 208 can be tuned to control the spectrum or wavelength of the laser light output by the DFB lasers 200/201/213/214 and/or a ratio between optical power of the laser light output from the front and back ends of these DFB lasers.

In the embodiments described above, the DFG 210 and the back reflector 206 of the DFB lasers 200/201/213/214 may comprise a first order diffraction grating. In other words, the first order diffraction of the DFG 210 is used to sustain the laser oscillation and the first order diffraction of the grating serving as back reflector is used to retroreflect light. In some other embodiments, a higher diffraction order of the DFG 210 may be used to sustain the laser oscillation and a higher diffraction order of the grating, serving as back reflector, may be used to retroreflect light. As such, in these embodiments, the ranges and numbers provided above for the length of period grating may, for example, be increased by a factor equal to the diffraction order used.

In some examples, tuning the back reflector 206 may comprise changing peak reflection wavelength and/or a reflection bandwidth associated with a peak reflection wavelength, via thermo-optic effect and/or an electro-optic effect, and by providing an electric current and/or electric voltage to at least a portion of the back reflector and/or heating element in thermal communication with the back reflector.

In some examples, tuning the phase control section 208 may comprise changing a length or a refractive index of at least a portion of the phase control section 208, via thermal expansion, thermo-optic effect, and/or an electro-optic effect and/or current injection effect (e.g., band shrinking, free carrier/plasma effects), and by providing an electric current and/or electric voltage to a portion of phase control section 208 and/or a heating element in thermal communication with the phase control section 208.

In various implementations, the optical gain region 204 may comprise a pumped optical gain material. In some examples, the optical gain material may comprise a compound semiconductor material. In some examples, the compound optical gain material may comprise two or more materials selected from the group: gallium nitride (GaN), Aluminum gallium nitride (AlGaN), gallium arsenide (GaAs), Indium Gallium Arsenide (InGaAs), indium phosphide (InP), Aluminum Indium Arsenide (AlInAs), indium gallium arsenide phosphide (InGaAsP), any ternary from InGaAsP, aluminum gallium arsenide (AlGaAs), indium aluminum gallium arsenide (InAlGaAs), indium aluminum phosphide (InAIP), indium aluminum gallium arsenide phosphide (InAlGaAsP) or any other ternary, quaternary, or quinternary compound. In some examples, the compound optical gain material may include a compound semiconductor material comprising Sb and configured to provide optical gain in mid-infrared wavelength range.

In various implementations, the back region 202 may comprise the same materials listed above with respect to the gain region 204. However, in various implementations, at least a portion of the back region may not be pumped to provide optical gain. In some cases, the back region 202 may comprise silicon, silicon nitride, silicon dioxide, or other materials that may facilitate integrating or interfacing the DFB lasers 200, 201, and 213 with a photonic device (e.g., a photonic device co-fabricated with the DFB laser on a common substrate).

In various implementations, the back region 202 may comprise a same or a different material compared to the optical gain region 204.

In various implementations, the back reflector 206, phase control section 208, and the DFG 210 may comprise the same or a different material.

In some examples, the back reflector 206 and at least a portion of the phase control section 208 may comprise an electro-optically and/or magneto-optically active material whose refractive index can be sufficiently tuned by a current, electric field, magnetic field or any combination thereof, to adjust an optical property (e.g., an effective refractive index) of the back reflector 206 and/or the phase control section 208.

In another implementation, the DFB laser comprises an optical waveguide (herein referred to as waveguide) disposed on a substrate. A gain region of the optical waveguide can be configured to provide optical gain to light guided by the waveguide (e.g., light propagating at least partially within the waveguide). The gain region may comprise a gain layer disposed within or above the waveguide or waveguide core. The DFB laser further comprises a distributed feedback grating (DFG) that provides distributed feedback along the waveguide for light propagating at least partially within a DFG region of the waveguide. The DFG region may be configured to allow interaction between light guided by the waveguide and a DFG disposed within, above, or otherwise close enough to the waveguide to allow interaction between DFG and guided light. The DFG region may at least partially overlap with the gain region and sustain laser oscillation within the DFB laser. Laser light can be generated and amplified within a gain region of the optical waveguide and output from an output port of the DFB laser. The DFB laser may further comprise a back reflector configured to retroreflect laser light output from the DFG region of the waveguide back to the DFG region. In various implementations, the back reflector can be a DBR or an SGDBR. The gain layer, the DFG and the back reflector may be disposed on the substrate close to or within the waveguide such that they can amplify, sustain, or reflect laser light propagating at least partially inside the waveguide. The DFG, the back reflector, and/or the gain layer may be disposed above or within a core region of the waveguide where laser light is largely confined. In some cases, the DFG and back reflector may be disposed on two separate waveguides that are in optical communication. In some cases, the optical waveguide of the DFB laser comprises a phase control section between the DFB and the back reflector configured to provide a fixed and/or tunable (e.g., electro-optically, thermo-optically, by current injection, or any combination thereof) optical phase delay for light transmitted from the DFG to the back reflector and vice versa. The phase control section of the waveguide may extend in the longitudinal direction from a first waveguide region optically coupled to the DFG and a second waveguide region optically coupled to the back reflector. Light output from the first waveguide region is transmitted to the second waveguide region and reflected by the back reflector to the first waveguide region via the phase control section.

In various implementations, a DFB laser may be formed from one or more layers such as doped semiconductor layers on a semiconductor substrate. The layers of the semiconductor may be fabricated, e.g., epitaxially grown, on the semiconductor substrate. The layers may comprise, for example, p and n type layers that form the gain layer, the waveguide, the grating or any combination thereof. Additionally, the DFB laser may comprise one or more metallic layers. In some cases, the DFB laser may comprise one or more dielectric layers. One or more semiconductor layers can be doped sufficiently to provide electrical conductivity, provide optical gain upon being pumped by an injection current (e.g., to form a p-n junction that provides optical gain), or form layers with other optical and electrical properties or any combination thereof.

In various implementations, the waveguide may comprise a ridge waveguide or a buried waveguide formed on the substrate. The waveguide may be formed from one or more layers configured to confine light in vertical and horizontal directions. In some examples, the waveguide may be formed by an upper cladding, a core, and a lower cladding. In some cases, e.g., when the waveguide comprises a ridge waveguide, the upper cladding function is provided by air and the lower cladding need not be a separate layer of material from the core region produced by the ridge. Other configurations and types of waveguides may be employed.

In various implementations, the optical gain layer may comprise one or more layers such as n type and p type doped semiconductor layers. In some examples, the optical gain layer may comprise a p-n junction and/or one or more quantum wells. In some cases, the optical gain layer can be a layer formed within the waveguide. In some other cases, the optical gain layer may be a layer disposed above the waveguide or waveguide core region and optically coupled to the waveguide.

In various implementations, a diffraction grating (e.g., the DFG, DBR, or SGDBR) may comprise a patterned layer formed within the waveguide or close enough to the waveguide to allow interaction between guided light and the periods of the grating. The patterned layer may comprise a periodic variation of refractive index, a periodic structure, or a layer configured to function as an optical grating. The periodic structure may comprise a layer patterned using photolithography and etching, or direct writing, etc.

### Wavelength Tuning of a DFB Laser Having a Reflector

In some implementations, controlling the spectrum of the laser light output by the DFB lasers 200/201/213 may comprise selecting or tuning a center wavelength of the output laser light (herein referred to as laser wavelength) using the back reflector. In some examples, controlling the spectrum of the laser light output by the DFB lasers 200/201/213 may comprise tuning a center wavelength of the output laser light, e.g., within a stopband of the DFG. In some examples, the center wavelength of the output laser light may be tuned by one or both of a phase control section (e.g., 208) and a back reflector (e.g., DBR 206). In some examples, the stop band can be from 0.001 nm to 0.01 nm, 0.01 nm to 0.1 nm, from 0.1 nm to 0.5 nm, from 0.5 nm to 1 nm, from 1 nm to 1.5 nm, from 1.5 nm to 2 nm, or any range formed by these values or larger or smaller. In some examples, a center wavelength and/or a dominant wavelength of the output laser output may be tuned within 1% to 5%, 5% to 20%, 10% to 30%, from 30% to 50%, 50% to 70%, or 70% to 100% of the stop band. In some of these implementations, the reflection spectrum of the back reflector 206 (e.g., a DBR or SGDBR) may be controlled to select or tune the laser wavelength (e.g., within a stopband of the DFG). In some cases, e.g., when the DFG 210 comprises an SGDBR, the DFG 210 may provide optical feedback at a plurality of peak feedback wavelengths. In some such cases, a peak reflection wavelength of the back reflector 206 (e.g., a DBR or another SGDBR) can be aligned with a selected peak feedback wavelength of the plurality of peak feedback wavelengths. In these cases, after such alignment, the reflected laser light received from the back reflector 206 may cause the DFB laser to lase (or oscillate) at a wavelength (or frequency) of the selected peak feedback wavelength (or frequency).

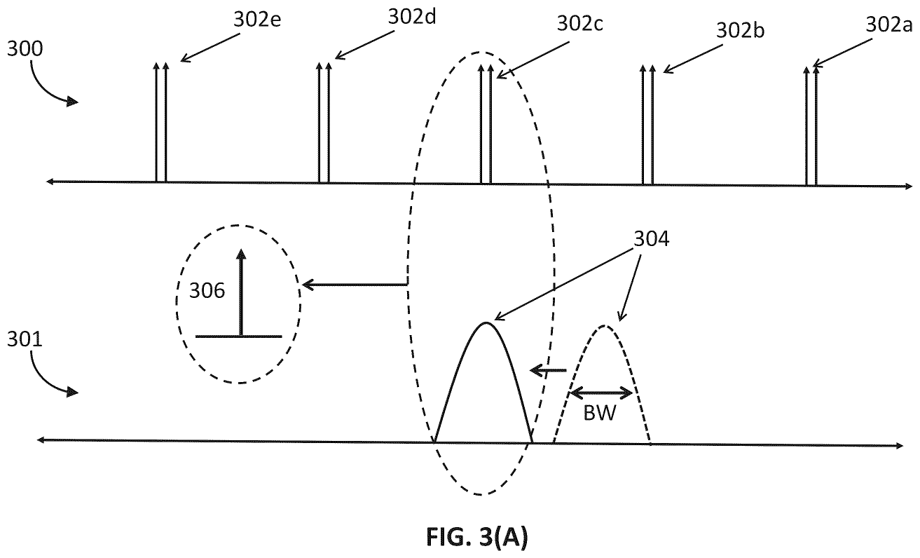

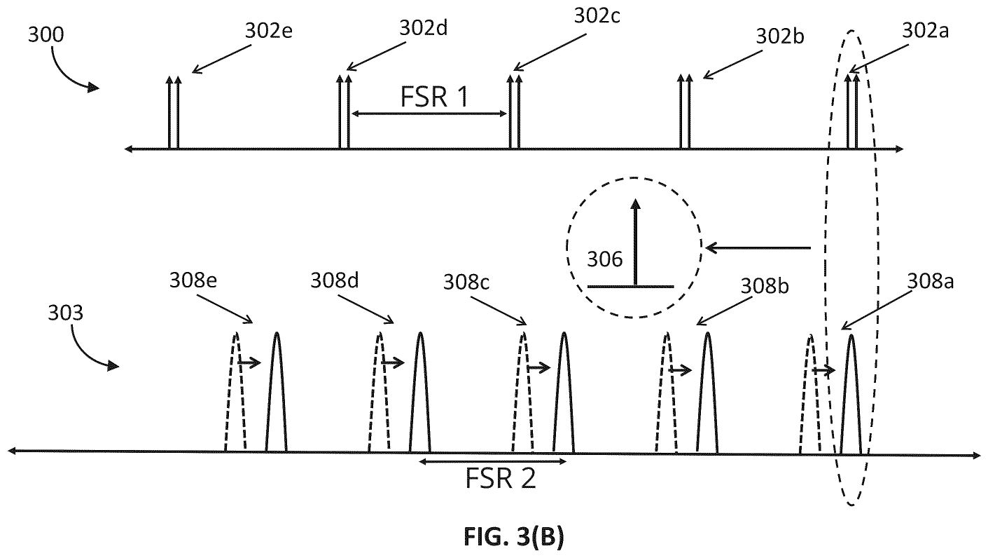

FIG. 3A schematically illustrates a spectrum 300 of laser light generated by an optical gain medium comprising a sampled grating distributed Bragg reflector (SGDBR) grating (top), and the reflection spectrum 301 of a distributed Bragg reflector (DBR) (bottom). In some cases, the DFG 210 and the back reflector 206 of a DFB laser (e.g., DFB laser 200, 201, or 213) may comprise such SGDBR and DBR, respectively. In these cases, the spectrum 300 can be the spectrum of the DFG 210 in the absence of the back reflector 206. The spectrum 300 comprises a series of equally spaced wavelength pairs 302a-302e, where each pair is associated with a pair of degenerate modes (propagating in opposite directions) of the DFG 210. The reflection spectrum 301 comprises a reflection peak 304 of the DBR (the back reflector 206) that comprises wavelengths within a reflection bandwidth (BW) centered at a peak reflection wavelength. In some examples, the reflection peak 304 can be tuned thermo-optically, electro-optically, or by current injection.

In the example shown, the reflection peak 304 is tuned such that it becomes aligned with the wavelength pair 302c. As a result, the laser light reflected by the DBR suppresses lasing in other wavelength pairs 302a-302b, 302d-302e. In some cases, once the wavelength pair 302c is selected by tuning the reflection peak 304, the phase control section may be tuned to suppress the wavelengths of the wavelength pair 302c, resulting in single mode oscillation of the DFB laser. The inset shows the output spectrum of a DFB laser (similar to the DFB lasers 200, 201, 213), that comprises a single laser line 306, when the reflection peak 304 is aligned with the wavelength pair 302c.

FIG. 3B schematically illustrates spectrum 300 of laser light generated by an optical gain medium comprising a first SGDBR (top), and the reflection spectrum 303 of a second SGDBR with no optical gain (bottom). In some cases, the DFG 210 and the back reflector 206 of a DFB laser (e.g., DFB laser 200, 201, or 213) may comprise the first and the second SGDBRs, respectively. The spectrum 300 comprises a series of equally spaced wavelength pairs 302a-302e, where each pair is associated with a pair of degenerate modes (propagating in opposite directions) of the DFG 210. In some cases, the wavelength spacing between the wavelength pairs 302a-302e may be substantially equal to a free-spectral-range FSR1 of the reflection peaks of the first SGDBR. The reflection spectrum 303 comprises a plurality of equally spaced reflection peaks 308a-308e having a free-spectral-range FSR2. In some cases, FSR2 can be different from FSR1. In some cases, a difference between FSR1 and FSR2 can be from 0.05 to 0.2 nm, from 0.2 to 1 nm, from 1 to 5 nm, or any range formed by any of these values or smaller or larger values. In some examples, the reflection peaks 308a-308e can be tuned thermo-optically, electro-optically, by current injection or by a combination thereof. In the example shown, the reflection peak 308a is tuned such that it becomes aligned with the wavelength pair 302a. As a result, the laser light reflected by the second SGDBR suppresses lasing in other wavelength pairs 308b-308c, and one of the wavelengths of the wavelength pair 302a, resulting in single mode oscillation of the DFB laser. The inset shows the output spectrum of the DFB laser, which comprises a single laser line 306, when the reflection peak 308a is aligned with the wavelength pair 302a and the phase control section is tuned to suppress one of the wavelengths in the wavelength pair 302a.

In various implementations, where the back reflector 206 comprises a tunable DBR (e.g., electro-optically or thermo-optically tuned or tuned by current injection), the schemes discussed above with respect to FIG. 3A may be used to tune the wavelength (e.g., the center wavelength) of the corresponding DFB laser from 0.1 to 0.5 nm, from 0.5 to 1 nm, from 1 to 1.5 nm, from 1.5 to 2 nm, from 2 to 3 nm or any range formed by these values, or larger or smaller values. In some cases, the wavelength (e.g., the center wavelength) may be tuned within a stopband of the DFG.

In various implementations, where the back reflector 206 comprises a tunable SGDBR (e.g., electro-optically or thermo-optically tuned or tuned by current injection), the schemes discussed above with respect to FIG. 3B may be used to select discrete wavelength pairs in the spectrum of the corresponding DFB. The discrete wavelength pairs may be spaced from 1 to 3 nm, from 3 to 5 nm, from 5 to 7 nm, from 7 to 10 nm or any ranges formed by these values or smaller or larger values.

### Integrated Photonic Circuits Comprising DFB Lasers Having Back Reflectors

In some cases, a passive or active region (e.g., waveguide region) or passive or active photonic device may be integrated with any of the DFB lasers 200, 201, 213, and 214 to receive a portion of light generated by the DFB laser. In various implementations, the region or the photonic device may comprise a photodetector, an optical modulator (e.g., electro-optical modulator), an attenuator, a polarization controller, an optical isolator, an optical switch, an optical filter or other optical devices that may receive the laser light generated by the DFB laser and output a modified laser light (e.g., filtered, modulated, attenuated, polarized, etc.) or generate an electrical signal based on the received light.

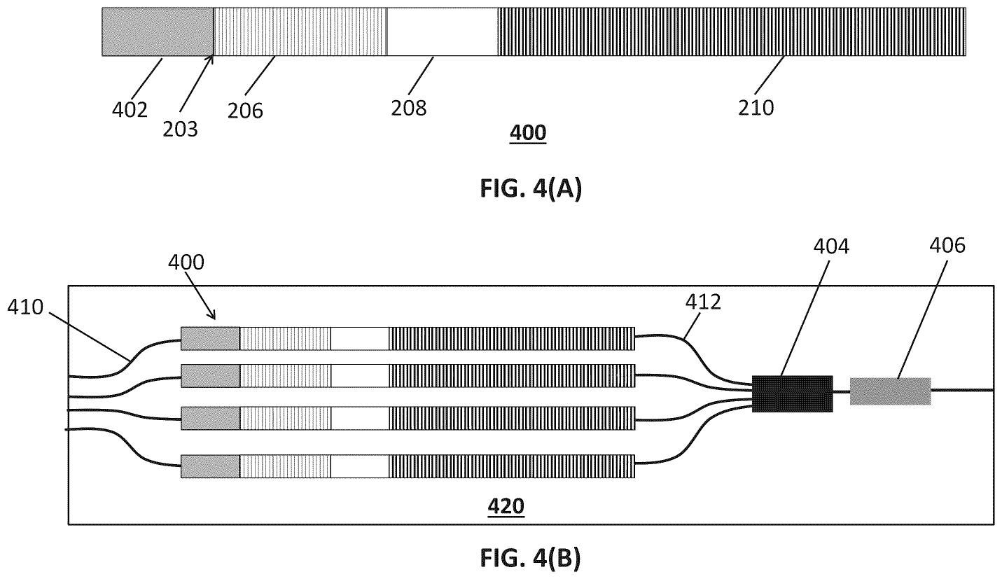

In some cases, the active optical device can be a photodetector that receives a portion of light generated by the DFB laser and generates a detector signal indicative of the optical power within the gain region and/or output by the DFB laser. In some examples, a DFB laser having a back reflector 206 may comprise a photodetection region or section configured to receive at least a portion of laser light transmitted through a back end of the back reflector 206 (e.g., a DBR or an SGDBR) and generate a photocurrent indicative of the optical power within the gain region and/or output by the DFB laser. In some cases, an electronic circuit may use the detector signal to generate a phase control signal and/or a wavelength control signal to control the phase control section 208 and/or the back reflector 206 (e.g., a peak reflection wavelength of a DBR or an SGDBR). FIG. 4A schematically illustrates an optical source 400 comprising a DFB laser similar to DFB lasers 200, 201 and an optical device 402 that shares an interface with the back reflector 206 and receives light from a back end 203 of the back reflector 206 (back end of the DFB laser). In some cases, the optical device 402 may comprise an active optical device. In implementations, the active optical device may comprise: a photodetector (e.g., P-i-N, avalanche, single-photon, or other types of photodetectors), an optical amplifier (e.g., a semiconductor optical amplifier or SOA), an optical modulator (e.g., a phase or amplitude modulator), or a variable optical attenuator (VOA), an optical filter (e.g., a ring resonator or a diffraction grating), a waveguide section, or any combination thereof. Other active devices may be integrated with the DFB laser section of the optical source 400. In some cases, the optical device 402 may comprise a passive optical device comprising, e.g., an optical filter, an optical power divider, an additional optical grating, an optical coupler, and the like or any combination of these.

In some cases, any of the DFB lasers 200, 201, 213, and 214 may be fabricated on a common chip and integrated (e.g., monolithically) with other optical devices on the chip (e.g., a photonic integrated circuit). FIG. 4B schematically illustrates an example photonic chip 420 comprising four optical devices similar to the optical source 400 fabricated on a single substrate and optically coupled to another optical device fabricated on the common substrate. In the example shown, a front end of an individual optical source 400 is optically connected to an optical power combiner 404 via a waveguide section 412. In some cases, the optical power combiner 404 is configured to receive laser light from the front ends of the four optical devices, combine them as a combined light beam, and transmit the combined light beam to another optical device 406 (e.g., an optical device integrated on the photonic chip 420). In some examples, the optical device 406 may comprise a photodetector, an optical modulator (e.g., electro-optical modulator), an attenuator, a polarization controller, an optical isolator, an optical switch, an optical filter or other optical devices. In some implementations, the laser light output from the optical device 402 that receives the laser light from the back end of the back reflector 206 of the optical source 400, may be coupled to a waveguide 410 and transmitted to other devices on the photonic chip 420.

### Example Structures of DFB Lasers Having Back Reflectors

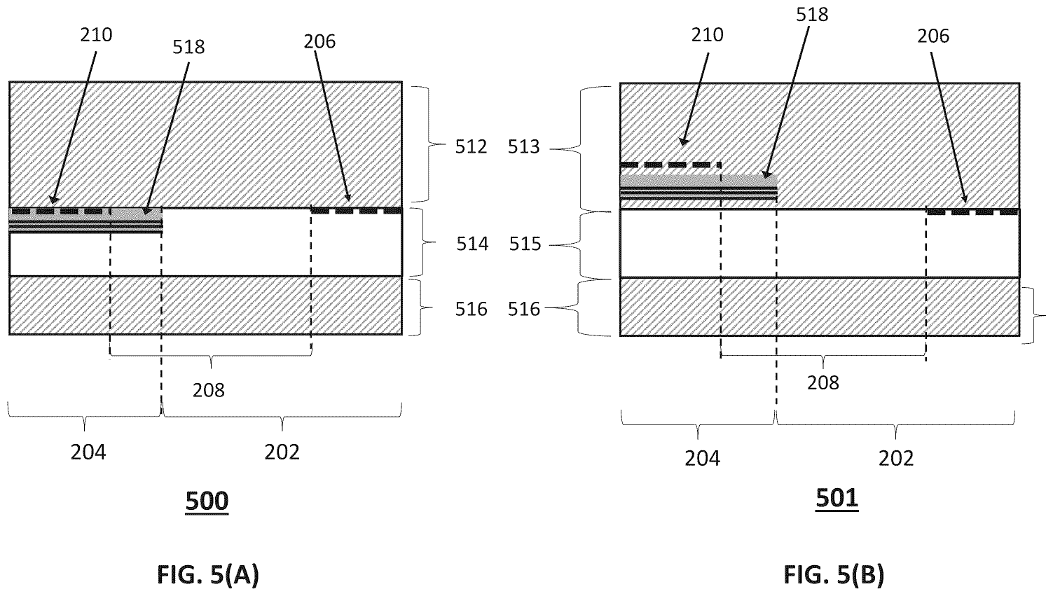

FIG. 5A schematically illustrates a vertical cross-section of an example DFB laser 500, similar to the DFB lasers 200/201 shown in FIG. 2A or 2B, having a DBR (or SGDBR) back reflector 206 according to one implementation. In some cases, the DFB laser 500 may be fabricated on a substrate and the vertical cross-section can be parallel to a vertical plane orthogonal to a major surface of the substrate and/or to a growth direction of the layers forming the DFB laser 500. In the example shown, the DFB laser may comprise a top cladding layer 512, a waveguide layer 514 and a bottom cladding layer 516. In some cases, any of these layers may comprise several sublayers. The top cladding layer 512 can comprise at least one contact layer and/or top electrode configured to provide a voltage or an injection current to a region or section of the DFB laser 500. In some implementations, the contact layer can be a doped semiconductor layer (e.g., a dope p-type semiconductor material) and the top electrode may comprise a metallic layer. The DFB laser 500 may further include a bottom electrode below the bottom cladding layer and configured to allow current flow through one or more sections of the DFB laser 500.

In some such cases, the top and bottom cladding layers 512/516, and waveguide layer 514 may be configured to at least partially confine laser light within the waveguide layer 514. For example, an optical refractive index of the waveguide layer 514 may be larger than the refractive index of the top cladding layer 512 and the refractive index of the bottom cladding layer 512. In some examples, the waveguide layer 514 of the DFB laser 500 may comprise a buried waveguide that at least partially confines the laser light in a lateral direction perpendicular to the vertical plane.

The DFB laser 500 may further comprise a gain layer 518 configured to provide optical gain to the laser light, upon being pumped by an electric current (e.g., injected to the gain layer 518 via the electrode and/or the contact layer). The gain layer 518 may comprise one or more quantum well sublayers, quantum wire sublayers, or quantum dot sublayers. In some cases, the quantum well sub-layers may be configured to support quantum cascade amplification.

In some examples, the gain layer 518 can be within the waveguide layer 514, the DFG 210, and DBR 206 may be formed within the waveguide layer 514. In some such examples, the DFG 210 may be formed within a region containing the gain layer 518. In some examples, the DBR 206 may be formed outside (e.g., above, or on top) of the waveguide layer 514. In some examples, the DFG may be below the waveguide, or above the waveguide, below the gain (wells) or above the gain (wells). In some examples, the DBR (or SGDBR) 206 may be below, in or above the waveguide.

In some cases, the top cladding layer 512, the waveguide layer 514 and/or the bottom cladding layer 516 may comprise semiconductor materials (e.g., doped semiconductor materials). The layers and the sublayers therein may comprise different types of semiconductor materials and may have different doping levels.

In various implementations, the semiconductor materials used to fabricate the layers and sublayers of the DFB laser 500 may include III-V semiconductor materials. In some implementations, the top cladding layer 512, the waveguide layer 514, the bottom cladding layer 516 or any combination thereof can include one or more materials selected from the group: gallium arsenide (GaAs), indium phosphide (InP), sapphire, silicon, or gallium nitride (GaN). In some cases, the layers or the sublayers may include binary, ternary, quaternary, and quinternary alloys and may be formed from one or more of the following: Ga, As, In, P, N, Al, Sb. The gain layer 518 can comprise one or more materials selected from the group: gallium arsenide (GaAs), Indium Gallium Arsenide (InGaAs), indium phosphide (InP), Aluminum Indium Arsenide (AlInAs), indium gallium arsenide phosphide (InGaAsP), any ternary from InGaAsP, aluminum gallium arsenide (AlGaAs), indium aluminum gallium arsenide (InAlGaAs), indium aluminum phosphide (InAIP), indium aluminum gallium arsenide phosphide (InAlGaAsP) or any other ternary, quaternary, or quinternary compound.

In various implementations, a thickness of the top cladding layer 512 (in a vertical direction) may be from 0.5 to 1 microns, from 1 to 2 microns, from 2 to 4 microns, or from 4 to 6 microns or 6 to 500 microns or any range formed by any of these values or large or smaller.

A thickness of the gain layer 518 (in a vertical direction) may be from 0.001 to 0.1 microns, from 0.1 to 1 microns, from 1 to 2 microns or any range formed by any of these values or large or smaller.

A thickness of the bottom layer 516 (in a vertical direction) may be from 0.5 to 1 microns, from 1 to 2 microns, from 2 to 4 microns, or from 4 to 6 microns or from 6 to 500 microns or any range formed by any of these values or large or smaller.

In some examples, the top and bottom electrodes may comprise one or more materials selected from the group: aluminum, gold, copper, tin, germanium, titanium, platinum, nickel, or any conductive alloy of these and other materials. Other materials may also be used. A thickness of any of the electrodes may be from 0.1 to 1 microns, from 1 to 2 microns, from 2 to 4 microns, or any range formed by any of these values or large or smaller. In one example design, the top electrode may be connected to a current source and the bottom electrode may be connected to a ground potential to support current injection to the gain layer 518 resulting in activation of at least a region (e.g., a region containing quantum wells, quantum wires or quantum dots or a bulk material) of the gain layer 518 although other configurations are possible.

FIG. 5B schematically illustrates a vertical cross-section of another example DFB laser 501 similar to the DFB lasers 200/201 shown in FIG. 2A or 2B, having a back reflector 206 (e.g., a DBR), according to one implementation. The DFB laser 501 may comprise one or more features described above with respect to the DFB laser 500.

In some such cases, the top and bottom cladding layers 513/516, and waveguide layer 514 may be configured to at least partially confine laser light within the waveguide layer 515. In some implementations, the top cladding layer 513 of the DFB laser 501 may comprise a ridge region configured to confine laser light in the lateral direction (perpendicular to the vertical plane). In some such implementations, a portion of laser light may reside in the ridge region.

In some examples, the gain layer 518 can be above the waveguide region, and the DFG 210 can be outside of the waveguide layer 515 (e.g., above or on top) of the gain layer 518. In some examples, the gain layer 518 can be outside of the waveguide region layer 513. In some such examples, the DFG 210 may be formed within the gain layer 518 or above the gain layer. In some examples, the DBR 206 may be formed outside (e.g., above, or on top) of the waveguide layer 515. In some examples, the DBR 206 may be formed within the waveguide layer 515.

### Example Embodiments

Example embodiments described herein have several features, no single one of which is indispensable or solely responsible for their desirable attributes. A variety of example systems and methods are provided below.

Example 1. A distributed feedback (DFB) laser comprising:
a pumped gain region comprising an optical gain medium configured to amplify light having a wavelength within an operational wavelength range of the DFB;
a first diffraction grating providing distributed optical feedback to the light amplified by the pumped gain region, the first diffraction grating extending from a back end to a front end along a longitudinal direction and configured to sustain laser oscillation within the DFB laser to produce laser light;
a back reflector configured to retroreflect laser light received from the back end of the first diffraction grating back to the first diffraction grating; and
a phase control section disposed along the longitudinal direction between the back reflector and the back end of the first diffraction grating, the phase control section configured to control the spectrum of the laser light,
wherein the gain region, the first diffraction grating, and the back reflector are formed on a common substrate.

Example 2. The DFB laser of Example 1, wherein the back reflector comprises a wavelength-selective reflector disposed outside the pumped gain region, wherein the wavelength-selective reflector does not provide optical gain.

Example 3. The DFB laser of Example 2, wherein the back reflector comprises a second diffraction grating.

Example 4. The DFB laser of Example 3, wherein the first diffraction grating has a first coupling coefficient, and the second diffraction grating has a second coupling coefficient greater than the first coupling coefficient by at least a factor of 1.1.

Example 5. The DFB laser of Example 4, wherein the first coupling coefficient is larger than the second coupling coefficient by at least a factor of 2.

Example 6. The DFB laser of Example 3, wherein the first diffraction grating has a first period and the second diffraction grating has a second period, wherein the first period is different from the second period.

Example 7. The DFB laser of Example 3, wherein the first diffraction grating, and the second diffraction grating comprise different materials.

Example 8. The DFB laser of Example 1, wherein at least a portion of the first diffraction grating does not overlap with the pumped gain region.

Example 9. The DFB laser of Example 1, wherein the DFB laser is disposed on a chip and the back reflector comprises a cleaved facet of the chip.

Example 10. The DFB laser of Example 1, wherein at least a portion of the phase control section is outside the pumped gain region and does not provide optical gain.

Example 11. The DFB laser of Example 10, wherein at least a portion of the phase control section at least longitudinally overlaps with the pumped gain region and provides optical gain to a portion of laser light output from the back end of the first diffraction grating.

Example 12. The DFB laser of Example 1, wherein the phase control section controls the spectrum of the laser light by controlling a relative phase of laser light received from the back end of the first diffraction grating and laser light reflected back to the first diffraction grating.

Example 13. The DFB laser of Example 1, wherein an optical path length through the phase control section is configured such that the spectrum of the laser light comprises a dominant mode near a midpoint of a stopband of the first diffraction grating.

Example 14. The DFB laser of Example 1, further comprising a pump electrode configured to provide an injection current to the pumped gain region.

Example 15. The DFB laser of Example 14, further comprising a phase control electrode wherein an optical path length of the phase control section is tuned by providing a phase control signal to the phase control electrode.

Example 16. The DFB laser of Example 15, wherein an optical path length through the phase control section is configured to be tuned by the phase control signal such that the spectrum of the laser light comprises a dominant mode near a center of a stopband of the first diffraction grating.

Example 17. The DFB laser of Example 15, wherein the phase control signal is configured to adjust a spectrum of the laser light by changing at least one of a side mode suppression ratio (SMSR) and a center laser wavelength of the laser light.

Example 18. The DFB laser of Example 17, wherein the SMSR of the laser light is greater than 10 dB.

Example 19. The DFB laser of Example 16, wherein the phase control signal is configured to tune the optical path length of the phase control section via electro-optical effect, thermo-optical effect, or by current injection.

Example 20. The DFB laser of Example 15, wherein the pump electrode is electrically isolated from the phase control electrode.

Example 21. The DFB laser of Example 15, further comprising an electronic circuit configured to control the phase control signal based at least in part on a measured spectrum of the laser light.

Example 22. The DFB laser of Example 3, further comprising a wavelength control electrode, wherein a reflection spectrum of the back reflector is tuned by providing a wavelength control signal to the wavelength control electrode.

Example 23. The DFB laser of Example 22, wherein the wavelength control signal is configured to tune a reflection band of the back reflector via electro-optical effect, thermo-optical effect, or by current injection.

Example 24. The DFB laser of Example 22, wherein the back reflector is tuned to at least adjust a wavelength of the laser light.

Example 25. The DFB laser of Example 22, further comprising an electronic circuit configured to control the wavelength control signal based at least in part on a measured spectrum or optical power of the laser light.

Example 26. The DFB laser of any of Examples 21 and 25, wherein the wavelength control signal and the phase control signal are generated by a photonic device that receives at least a portion of the laser light from the DFB laser and is fabricated on the common substrate.

Example 27. The DFB laser of any of Examples 21 and 25, wherein the wavelength control signal or the phase control signal comprise a voltage measured across a thickness of the pumped gain region.

Example 28. The DFB laser of Example 1, wherein a side mode suppression ratio (SMSR) of the laser light is greater than 10 dB.

Example 29. The DFB laser of Example 1, wherein the first diffraction grating, and at least a portion of the phase control section comprise the same material.

Example 30. The DFB laser of Example 1, wherein the first diffraction grating comprises a sampled grating distributed Bragg reflector (SGDBR) or a distributed Bragg grating (DBR).

Example 31. The DFB laser of Example 2, wherein the back reflector comprises a sampled grating distributed Bragg reflector (SGDBR), a distributed Bragg grating (DBR), or a ring resonator reflector.

Example 32. The DFB laser of Example 3, wherein the common substrate comprises a top cladding layer, a waveguide layer, and a bottom cladding layer configured to form a waveguide.

Example 33. The DFB laser of Example 32, wherein the waveguide comprises a ridge waveguide.

Example 34. The DFB laser of Example 32, wherein the waveguide comprises a buried waveguide.

Example 35. The DFB laser of Example 32, wherein the gain region comprises a gain layer disposed within the waveguide layer.

Example 36. The DFB laser of Example 32, wherein the gain region comprises a gain layer disposed outside the waveguide layer.

Example 37. The DFB laser of Example 32, wherein the first diffraction grating is disposed within the waveguide layer.

Example 38. The DFB laser of Example 32, wherein the second diffraction grating is disposed within the waveguide layer.

Example 39. The DFB laser of Example 32, wherein the first diffraction grating is outside the waveguide layer.

Example 40. The DFB laser of Example 32, wherein the second diffraction grating is outside the waveguide layer.

Example 41. The DFB laser of Example 1, wherein the laser light is output at least through the front end of the first diffraction grating.

Example 42. The DFB laser of Example 2, wherein the back reflector is optically coupled to an optical device fabricated on the common substrate.

Example 43. The DFB laser of Example 42, wherein the optical device comprises a photodetector.

### Terminology

Conditional language, such as “can,” “could,” “might,” or “may,” unless specifically stated otherwise, or otherwise understood within the context as used, is generally intended to convey that certain embodiments include, while other embodiments do not include, certain features, elements, and/or steps. Thus, such conditional language is not generally intended to imply that features, elements, and/or steps are in any way required for one or more embodiments.

Conjunctive language such as the phrase “at least one of X, Y, and Z,” unless specifically stated otherwise, is to be understood within the context used in general to convey that an item, term, etc. may be either X, Y, or Z. Thus, such conjunctive language is not generally intended to imply that certain embodiments require the presence of at least one of X, at least one of Y, and at least one of Z.

Language of degree, as used herein, such as the terms “approximately,” “about,” “generally,” and “substantially,” represent a value, amount, or characteristic close to the stated value, amount, or characteristic that still performs a desired function or achieves a desired result. For example, the terms “approximately,” “about,” “generally,” and “substantially” may refer to an amount that is within ±10% of, within ±5% of, within ±2% of, within ±1% of, or within ±0.1% of the stated amount. As another example, the terms “generally parallel” and “substantially parallel” refer to a value, amount, or characteristic that departs from exactly parallel by ±10 degrees, by ±5 degrees, by ±2 degrees, by ±1 degree, or by ±0.1 degree, and the terms “generally perpendicular” and “substantially perpendicular” refer to a value, amount, or characteristic that departs from exactly perpendicular by ±10 degrees, by ±5 degrees, by ±2 degrees, by ±1 degree, or by ±0.1 degree.

Various configurations have been described above. Although this invention has been described with reference to these specific configurations, the descriptions are intended to be illustrative of the invention and are not intended to be limiting. Various modifications and applications may occur to those skilled in the art without departing from the true spirit and scope of the invention. Thus, for example, in any method or process disclosed herein, the acts or operations making up the method/process may be performed in any suitable sequence and are not necessarily limited to any particular disclosed sequence. Features or elements from various embodiments and examples discussed above may be combined with one another to produce alternative configurations compatible with embodiments disclosed herein. Various aspects and advantages of the embodiments have been described where appropriate. It is to be understood that not necessarily all such aspects or advantages may be achieved in accordance with any particular embodiment. Thus, for example, it should be recognized that the various embodiments may be carried out in a manner that achieves or optimizes one advantage or group of advantages as taught herein without necessarily achieving other aspects or advantages as may be taught or suggested herein.

What is claimed is:

1. A distributed feedback (DFB) laser comprising:
a pumped gain region comprising an optical gain medium configured to amplify light having a wavelength within an operational wavelength range of the DFB;
a first diffraction grating providing distributed optical feedback to the light amplified by the pumped gain region, the first diffraction grating extending from a back end to a front end along a longitudinal direction and configured to sustain laser oscillation within the DFB laser to produce laser light;
a back reflector configured to retroreflect laser light received from the back end of the first diffraction grating back to the first diffraction grating; and
a phase control section disposed along the longitudinal direction between the back reflector and the back end of the first diffraction grating, the phase control section configured to control a spectrum of the laser light, wherein the gain region, the first diffraction grating, and the back reflector are formed on a common substrate.

2. The DFB laser of claim 1, wherein the back reflector comprises a wavelength-selective reflector disposed outside the pumped gain region, wherein the wavelength-selective reflector does not provide optical gain.

3. The DFB laser of claim 2, wherein the back reflector comprises a second diffraction grating.

4. The DFB laser of claim 3, wherein the first diffraction grating has a first coupling coefficient, and the second diffraction grating has a second coupling coefficient greater than the first coupling coefficient by at least a factor of 1.1.

5. The DFB laser of claim 3, wherein the first diffraction grating has a first period and the second diffraction grating has a second period, wherein the first period is different from the second period.

6. The DFB laser of claim 3, wherein the first diffraction grating, and the second diffraction grating comprise different materials.

7. The DFB laser of claim 1, wherein at least a portion of the first diffraction grating does not overlap with the pumped gain region.

8. The DFB laser of claim 1, wherein the DFB laser is disposed on a chip and the back reflector comprises a cleaved facet of the chip.

9. The DFB laser of claim 1, wherein at least a portion of the phase control section is outside the pumped gain region and does not provide optical gain.

10. The DFB laser of claim 1, wherein the phase control section controls the spectrum of the laser light by controlling a relative phase of laser light received from the back end of the first diffraction grating and laser light reflected back to the first diffraction grating.

11. The DFB laser of claim 1, wherein an optical path length through the phase control section is configured such that the spectrum of the laser light comprises a dominant mode near a midpoint of a stopband of the first diffraction grating.

12. The DFB laser of claim 1, further comprising a pump electrode configured to provide an injection current to the pumped gain region.

13. The DFB laser of claim 3, further comprising a wavelength control electrode, wherein a reflection spectrum of the back reflector is tuned by providing a wavelength control signal to the wavelength control electrode.

14. The DFB laser of claim 1, wherein a side mode suppression ratio (SMSR) of the laser light is greater than 10 dB.

15. The DFB laser of claim 1, wherein the first diffraction grating, and at least a portion of the phase control section comprise the same material.

16. The DFB laser of claim 1, wherein the first diffraction grating comprises a sampled grating distributed Bragg reflector (SGDBR) or a distributed Bragg grating (DBR).

17. The DFB laser of claim 2, wherein the back reflector comprises a sampled grating distributed Bragg reflector (SGDBR), a distributed Bragg grating (DBR), or a ring resonator reflector.

18. The DFB laser of claim 3, wherein the common substrate comprises a top cladding layer, a waveguide layer, and a bottom cladding layer configured to form a waveguide.

19. The DFB laser of claim 1, wherein the laser light is output at least through the front end of the first diffraction grating.

20. A method of fabricating a distributed feedback (DFB) laser comprising:
forming, on a common substrate, a pumped gain region, a first diffraction grating, and a back reflector,
wherein the pumped gain region comprises an optical gain medium configured to amplify light having a wavelength within an operational wavelength range of the DFB,
wherein the first diffraction grating provides distributed optical feedback to the light amplified by the pumped gain region, the first diffraction grating extending from a back end to a front end along a longitudinal direction and configured to sustain laser oscillation within the DFB laser to produce laser light,
wherein the back reflector is configured to retroreflect laser light received from the back end of the first diffraction grating back to the first diffraction grating, and
wherein a phase control section is disposed along the longitudinal direction between the back reflector and the back end of the first diffraction grating, the phase control section configured to control a spectrum of the laser light.
